(19) United States
(12) Patent Application Publication
(10) Pub. No.: US 2026/0327062 A1
(43) Pub. Date: Oct. 22, 2026

(54) MEMS DEVICE WITH IMPROVED MEASUREMENT RELIABILITY AND IMPROVED MECHANICAL ROBUSTNESS

(71) Applicant: STMicroelectronics International N.V., Geneva (CH)

(72) Inventors: Francesco RIZZINI, Passirano (IT); Nicolo' MANCA, Torino (IT)

(73) Assignee: STMicroelectronics International N.V., Geneva (CH)

(21) Appl. No.: 19/652,164

(22) Filed: Apr. 20, 2026

(30) Foreign Application Priority Data
Apr. 22, 2025 (IT) 102025000009057

(51) Int. Cl. B81B 3/00; B81C 1/00

(52) U.S. Cl. CPC B81B 3/0056; B81C 1/00198; B81B 2201/0235; B81B 2201/0242; B81B 2203/0163; B81B 2203/0307; B81B 2203/04

(57) ABSTRACT

Disclosed herein is a MEMS device including a frame body, a seismic mass elastically coupled to the frame body, a stopper/sense structure elastically coupled to the frame body. The stopper/sense structure is configured to move with respect to the frame body and to limit the movement of the seismic mass with respect to the frame body or to sense the position of the seismic mass. A stopper/sense actuation group is fixed to the frame body and configured to control the position of the stopper/sense structure in such a way as to vary an adjustable distance between the stopper/sense structure and the seismic mass.

### PRIORITY CLAIM

This application claims the priority benefit of Italian Application for Patent No. 102025000009057 filed on Apr. 22, 2025, the content of which is hereby incorporated by reference in its entirety to the maximum extent allowable by law.

### TECHNICAL FIELD

The present invention relates to a microelectromechanical systems (MEMS) device with improved measurement reliability and improved mechanical robustness. In particular, it relates to a MEMS-type device having a movable-type stopper structure and/or a sense structure, and to a manufacturing process for the device.

### BACKGROUND

As is known, MEMS are electromechanical systems often used as sensors or actuators in a variety of applications.

The current market requires high performance in terms of robustness and reliability, in particular with regard to the control of performance spread, that is, the variability of performance between devices of the same family due to manufacturing tolerances. Furthermore, layout limitations due to the manufacturing process often used significantly limit further improvements and design developments.

In particular, the performance of MEMS devices is influenced and limited by the inevitable tolerances and spreads of manufacturing processes.

For example, critical parameters during the manufacturing step are notoriously the minimum dimension of the lithographic process used, the dimensional loss (“CD_loss”, the critical dimension loss, also referred to as here the intrinsic dimensional loss) and the spread dimensional loss (“CD_loss_spread”). In particular, the intrinsic dimensional loss is indicative of the gap between the ideal position of a MEMS element (i.e., its position in the design step) and its real average position (i.e. an average value of the real measured positions of this element in a plurality of MEMS manufactured according to the same manufacturing process). On the other hand, the spread dimensional loss is indicative of the spread of the real position of this MEMS element with respect to its real average position and is therefore a statistical parameter indicative of the spread of the real position of this MEMS element.

The minimum dimension of the lithographic process used causes the existence of a lower limit on the distance between two MEMS elements, for example between a movable element and a corresponding stopper element, ensuring that it is not possible to reduce the stroke of the seismic mass below a certain threshold value.

On the other hand, the spread dimensional loss causes, for example in capacitive MEMS devices, a spread of parameters and properties such as electrical sensitivity. In fact, variation in the distance between capacitor plates generates a corresponding spread of measurement sensitivity, which is dependent on the distance between the capacitor plates (in detail, it is inversely proportional to the square of this distance). In other words, MEMS sensitivity is typically defined by a Gaussian distribution centered on an average sensitivity of the MEMS, whose spread is correlated to the spread of the distance between the plates.

For example, in an inertial-type MEMS device with capacitive sensing and a seismic mass that oscillates elastically with respect to a frame body during use, sensing electrodes (for capacitive sensing of the oscillation of the seismic mass) and stopper elements (for limiting the oscillations of the seismic mass) are typically fixed to the frame body at predefined positions. Nevertheless, such a device is affected by the issues described above. In particular, in the static case, the distances between the sensing electrodes or stopper elements and the seismic mass cannot be smaller than the minimum dimension of the lithographic process used and indeed have, in addition to the ideal design value, a first contribution due to the intrinsic dimensional loss and a second contribution due to the spread dimensional loss.

In the case of an inertial-type MEMS device, these critical parameters limit the full-scale oscillation of the seismic mass and the mechanical robustness in the case of stopper elements, and negatively impact the measurement sensitivity in the case of sensing electrodes.

The manufacturing limits that influence the definition of the minimum dimension might ideally be overcome with the development of new technology and manufacturing process capable of overcoming the current limits. However, the development of a new technology and a new manufacturing process implies a significant additional research and development cost and longer lead times to obtain the MEMS, therefore it is not an option that may be implemented in practice in a simple and immediate manner.

The current common strategy to overcome these drawbacks is based on the consideration of these limits in the design step, in order to design the MEMS in such a way as to ensure its correct operation in any case. However, this leads to a more complicated design that takes into account a greater number of design constraints, and above all to reduced final performance of the MEMS.

There is a need to provide a MEMS-type device and a manufacturing process that overcome the drawbacks of the prior art.

### SUMMARY

According to the present invention, a MEMS-type device and a manufacturing process are provided.

To that end, a MEMS device is provided that includes a frame body, a seismic mass elastically coupled to the frame body and configured to oscillate with respect to the frame body, a stopper structure elastically coupled to the frame body and configured to move with respect to the frame body and to limit movement of the seismic mass with respect to the frame body, and a stopper actuation group fixed to the frame body and configured to control position of the stopper structure with respect to the frame body so as to vary an adjustable distance between the stopper structure and the seismic mass.

In some embodiments, the stopper actuation group is electrically controllable to move the stopper structure from a first position to a second position, with the adjustable distance between the stopper structure and the seismic mass being smaller in the second position than in the first position.

In some embodiments, the stopper actuation group is configured to selectively control the stopper structure in a free state or in a contact state, where in the free state the stopper structure is at a distance from the stopper actuation group and is movable with respect to the frame body, and where in the contact state the stopper structure is in contact with the stopper actuation group and is fixed with respect to the frame body.

In some embodiments, the stopper structure has a first stopper mass distance from the seismic mass in the contact state and a second stopper mass distance from the seismic mass in the free state, with the first stopper mass distance being lower than the second stopper mass distance, and with the first stopper mass distance being substantially zero when the seismic mass is subject to an acceleration equal to or greater than an acceleration threshold value.

In some embodiments, the stopper actuation group includes a fixed stopper element and a fixed stopper actuation element fixed to the frame body, where the fixed stopper actuation element is electrically controllable to move the stopper structure toward the fixed stopper element, and where the fixed stopper element limits movement of the stopper structure with respect to the frame body.

In some embodiments, in the contact state the stopper structure has a first stopper electrode distance from the fixed stopper actuation element and is in contact with the fixed stopper element, and in the free state the stopper structure has a second stopper electrode distance from the fixed stopper actuation element and a stopper stopper distance from the fixed stopper element, with the second stopper electrode distance being greater than the first stopper electrode distance.

In some embodiments, the seismic mass oscillates with respect to the frame body along an oscillation direction and has first and second external side walls opposite one another along the oscillation direction, with a respective stopper structure and a respective stopper actuation group associated with each external side wall, where each stopper structure includes at least one contact region and at least one stopper electrode, and where the contact region selectively contacts the respective external side wall and the respective fixed stopper element depending on acceleration conditions.

In some embodiments, the MEMS device further includes a sense structure and a sense actuation group in addition to the stopper structure and the stopper actuation group.

A MEMS device is also provided that includes a frame body, a seismic mass elastically coupled to the frame body and configured to oscillate with respect to the frame body, a sense structure elastically coupled to the frame body and configured to move with respect to the frame body and to sense position of the seismic mass, and a sense actuation group fixed to the frame body and configured to control position of the sense structure with respect to the frame body so as to vary an adjustable distance between the sense structure and the seismic mass.

In some embodiments, the sense actuation group is electrically controllable to move the sense structure from a first position to a second position, with the adjustable distance between the sense structure and the seismic mass being smaller in the second position than in the first position.

In some embodiments, the sense actuation group selectively controls the sense structure in a free state or in a contact state, where in the free state the sense structure is at a distance from the sense actuation group and is movable with respect to the frame body, and where in the contact state the sense structure is in contact with the sense actuation group and is fixed with respect to the frame body.

In some embodiments, the sense structure has a first mass electrode distance from the seismic mass in the contact state and a second mass electrode distance from the seismic mass in the free state, with the first mass electrode distance being smaller than the second mass electrode distance, and with the first mass electrode distance being substantially zero when the seismic mass is subject to an acceleration equal to or greater than an acceleration threshold value.

In some embodiments, the sense actuation group includes a fixed sense element and a fixed sense actuation element fixed to the frame body, where the fixed sense actuation element is electrically controllable to move the sense structure toward the fixed sense element, and where the fixed sense element limits movement of the sense structure with respect to the frame body.

In some embodiments, the sense actuation group selectively controls the sense structure in a free state or in a contact state, with defined electrode electrode distances between the sense structure and the fixed sense actuation element that differ between the free state and the contact state.

In some embodiments, the seismic mass oscillates along an oscillation direction and includes a main body with a through opening that carries ground electrodes, while the sense structure extends into the through opening and carries sense electrodes interdigitated with the ground electrodes to capacitively sense position of the seismic mass.

In some embodiments, the MEMS device is symmetrical with respect to a first median axis of symmetry coinciding with the oscillation direction and a second median axis of symmetry orthogonal to the oscillation direction.

A process for manufacturing a MEMS device is also provided, in which a seismic mass is formed on a frame body so as to be elastically coupled to the frame body and configured to oscillate with respect to the frame body, and in which at least one of a stopper structure and stopper actuation group or a sense structure and sense actuation group is formed on the frame body, with the stopper structure and sense structure being movable with respect to the frame body and having adjustable distances relative to the seismic mass.

### BRIEF DESCRIPTION OF THE DRAWINGS

For a better understanding of the present invention, a preferred embodiment is now described, purely by way of non-limiting example, with reference to the attached drawings, wherein:

FIG. 1 shows a schematic top view of a MEMS-type device according to one embodiment and in an operating configuration.

FIG. 2 shows a schematic top view of the MEMS-type device of FIG. 1 in a different operating configuration.

FIG. 3 shows a top view of a different embodiment of the MEMS-type device.

### DETAILED DESCRIPTION

In particular, the Figures are shown with reference to a triaxial Cartesian system defined by an X-axis, a Y-axis and a Z-axis, orthogonal to each other.

In the following description, elements common to the different embodiments have been indicated with the same reference numbers.

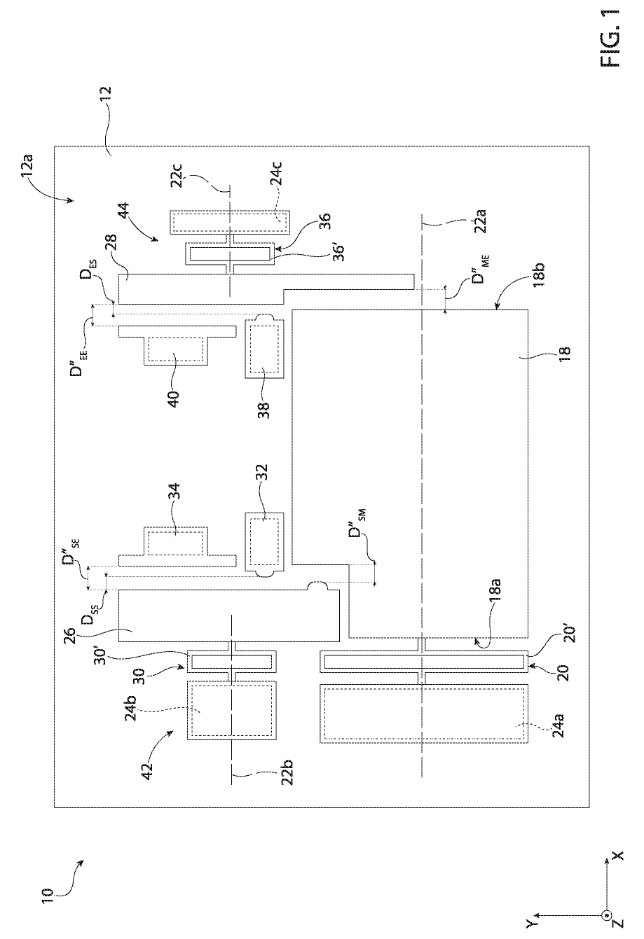

FIG. 1 shows a device 10 of the MEMS type, in particular of the inertial type, here exemplarily a MEMS accelerometer, for example of the monoaxial type, in a Cartesian reference system XYZ comprising an X-axis, a Y-axis, and a Z-axis.

In the following description, it is exemplarily assumed that the gravitational force acts along the Z-axis, which therefore defines a gravity axis or vertical axis.

In FIG. 1, only the elements useful for understanding the present embodiment are illustrated, and elements or components that, although present in the finished device, are not relevant to the present invention are not shown.

The device 10 is formed using micromachining techniques starting from a body of semiconductor material, for example silicon.

The device 10 comprises a semiconductor body, hereinafter also referred to as a frame body 12, having an upper surface 12a and a lower surface (not shown), opposite each other along the Z-axis.

The device 10 comprises a seismic mass 18 elastically coupled to the frame body 12 such that, in use, the seismic mass 18 can move (in detail, oscillate elastically) with respect to the frame body 12, in particular along a first oscillation direction 22a.

In detail, the device 10 comprises a mass anchoring region 24a fixed to the frame body 12 and extending on the upper surface 12a of the frame body 12 along the Z-axis. The seismic mass 18 is elastically coupled to the mass anchoring region 24a.

In the embodiment exemplarily described in FIG. 1, the first oscillation direction 22a is shown parallel to the X-axis, indicating that the seismic mass 18 can oscillate along the X-axis, alternately moving away from and toward the mass anchoring region 24a. Nevertheless, other embodiments may similarly be considered, for example in which the seismic mass 18 oscillates along the Y-axis or the Z-axis, or along any combination of these axes. In the following, for simplicity of description, reference is made only to the case in which the first oscillation direction 22a is parallel to the X-axis.

As shown in FIG. 1, the seismic mass 18 extends above the frame body 12 along the Z-axis at a distance therefrom. In other words, the upper surface 12aof the frame body 12 faces the seismic mass 18 along the Z-axis.

In particular, the device 10 further comprises a mass elastic group 20 interposed, here exemplarily along the X-axis, between the seismic mass 18 and the mass anchoring region 24a. Nevertheless, other embodiments may similarly be considered, for example in which the mass elastic group 20 is interposed between the seismic mass 18 and the upper surface 12a of the frame body 12 along the Z-axis. In the following, for simplicity of description, reference is made to the case in which the mass elastic group 20 is interposed between the seismic mass 18 and the mass anchoring region 24a.

The mass elastic group 20, of the elastic type, elastically couples the seismic mass 18 to the frame body 12, allowing movement of the seismic mass 18 along the first oscillation direction 22a during use.

In detail, the mass elastic group 20 comprises one or more mass elastic elements, such as springs, for example of the folded type, which may have a bellows or serpentine path and are elastically deformable when the seismic mass 18 undergoes acceleration along the first oscillation direction 22a.

In the example of FIG. 1, only a first mass elastic element 20’ is present, interposed between the seismic mass 18 and the mass anchoring region 24a. Nevertheless, other numbers and arrangements of mass elastic elements may similarly be considered.

Furthermore, the seismic mass 18 has a first side wall 18a and a second side wall 18b, opposite each other along the first oscillation direction 22a.

The device 10 further comprises at least one adjustable element elastically coupled to the frame body 12 so as to be movable with respect to the frame body 12 and selectively controllable, in particular capacitively, as better described below.

According to the embodiment of FIG. 1, the device 10 comprises at least two adjustable elements, namely a stopper structure 26 and a sense structure 28.

Nevertheless, as described in greater detail below, the device 10 may comprise only the stopper structure 26, only the sense structure 28, or any combination of one or more stopper structures 26 and one or more sense structures 28. In the following description, the case of a stopper structure 26 and a sense structure 28 is exemplarily considered.

The stopper structure 26 is elastically coupled to the frame body 12 such that, in use, the stopper structure 26 may move with respect to the frame body 12, in particular along a second oscillation direction 22b.

The second oscillation direction 22b is shown here parallel to the first oscillation direction 22a. Nevertheless, other configurations may be considered, for example in which the second oscillation direction 22b coincides with, or is transverse or orthogonal to, the first oscillation direction 22a.

In detail, the device 10 comprises a stopper anchoring region 24b fixed to the frame body 12 and extending on the upper surface 12a of the frame body 12 along the Z-axis. The stopper structure 26 is elastically coupled to the stopper anchoring region 24b.

In the embodiment exemplarily described in FIG. 1, the second oscillation direction 22b is shown parallel to the X-axis, indicating that the stopper structure 26 may move along the direction of the X-axis, away from or toward the stopper anchoring region 24b. Nevertheless, other embodiments may similarly be considered, for example in which the stopper structure 26 moves along the Y-axis or the Z-axis, or along any combination of these axes. In the following description, for simplicity, reference is made, for simplicity of description, only to the case in which the second oscillation direction 22b is parallel to the X-axis.

As shown in FIG. 1, the stopper structure 26 extends above the frame body 12 along the Z-axis at a distance therefrom. In other words, the upper surface 12a of the frame body 12 faces the stopper structure 26 along the Z-axis.

Furthermore, in FIG. 1 the stopper structure 26 faces, at least in part, the first side wall 18a of the seismic mass 18 along the X-axis and therefore along the first oscillation direction 22a. Nevertheless, other arrangements may similarly be considered, for example in which the stopper structure 26 faces, at least in part, the second side wall 18b of the seismic mass 18 along the first oscillation direction 22a.

In particular, the device 10 further comprises a stopper elastic group 30 interposed, here exemplarily along the X-axis, between the stopper structure 26 and the stopper anchoring region 24b. Nevertheless, other embodiments may similarly be considered, for example in which the stopper elastic group 30 is interposed between the stopper structure 26 and the upper surface 12a of the frame body 12 along the Z-axis. In the following description, for simplicity, reference is made to the case in which the stopper elastic group 30 is interposed between the stopper structure 26 and the stopper anchoring region 24b.

The stopper elastic group 30, of the elastic type, elastically couples the stopper structure 26 to the frame body 12, allowing oscillation of the stopper structure 26 along the second oscillation direction 22b during use.

In detail, the stopper elastic group 30 comprises one or more stopper elastic elements, such as springs, for example of the folded type, which may have a bellows or serpentine path and are elastically deformable along the second oscillation direction 22b.

In the example of FIG. 1, only a first stopper elastic element 30’ is present, interposed between the stopper structure 26 and the stopper anchoring region 24b. Nevertheless, other numbers and arrangements of stopper elastic elements may similarly be considered.

The device 10 further comprises a fixed stopper element (or fixed stopper element of stopper) 32 and a fixed stopper actuation element (or fixed stopper actuation element of stopper) 34, fixed to the frame body 12 and defining a stopper actuation group configured to control the position of the stopper structure 26. In the case of multiple stopper structures 26, a respective fixed stopper element 32 and a respective fixed stopper actuation element 34 are provided for each stopper structure 26.

The fixed stopper element 32 and the fixed stopper actuation element 34 extend on the upper surface 12a of the frame body 12 at a distance from the stopper structure 26 and face the stopper structure 26 along the second oscillation direction 22b.

The fixed stopper element 32 and the fixed stopper actuation element 34 are shown arranged side by side to each other along the Y-axis and facing the same side of the stopper structure 26. Nevertheless, other arrangements may similarly be considered, as better described below.

As better described below, along the second oscillation direction 22b, the fixed stopper element 32 is closer to the stopper structure 26 than the fixed stopper actuation element 34.

The fixed stopper actuation element 34 is configured to control the position of the stopper structure 26 with respect to the frame body 12, in particular capacitively. In use, the fixed stopper actuation element 34 is electrically controllable so as to generate an electrostatic force (also referred to as the electrostatic stopper force) between the fixed stopper actuation element 34 and the stopper structure 26, which moves the stopper structure 26 toward the fixed stopper element 32 along the second oscillation direction 22b.

The fixed stopper element 32 is instead a stopper element configured to limit movement of the stopper structure 26. Given the relative positions of the fixed stopper element 32 and the fixed stopper actuation element 34 with respect to the stopper structure 26, when the electrostatic force between the fixed stopper actuation element 34 and the stopper structure 26 is greater than a threshold value, the stopper structure 26 abuts against (i.e. is in contact with) the fixed stopper element 32, thus preventing the stopper structure 26 from impacting the fixed stopper actuation element 34.

Accordingly, during use, the stopper structure 26 is operable in a free state (or first state, oscillation state) or in a contact state (or second state, fixed state). In the free state, the electrostatic force between the fixed stopper actuation element 34 and the stopper structure 26 is lower than the threshold value, and the stopper structure 26 is spaced from the fixed stopper element 32 (free position of the stopper structure 26) and is free to move along the second oscillation direction 22b. In the contact state, the electrostatic force between the fixed stopper actuation element 34 and the stopper structure 26 is equal to or greater than the threshold value, and therefore the stopper structure 26 is in contact with the fixed stopper element 32 (contact position of the stopper structure 26) and the electrostatic force prevents it from continuing to move along the second oscillation direction 22b, stacking it in its contact position.

Accordingly, the stopper structure 26, the stopper anchoring region 24b, the stopper elastic group 30, the fixed stopper element 32, and the fixed stopper actuation element 34 together define a stopper group 42, wherein the stopper structure 26 is movable with respect to the frame body 12 and electrically controllable.

Again with reference to FIG. 1, the sense structure 28 is elastically coupled to the frame body 12 such that, in use, the sense structure 28 can move with respect to the frame body 12, in particular along a third oscillation direction 22c.

The third oscillation direction 22c is shown here parallel to the first oscillation direction 22a and substantially aligned with the second oscillation direction 22b. Nevertheless, other configurations may similarly be considered, for example in which the third oscillation direction 22c coincides with, or is transverse or orthogonal to, the first oscillation direction 22a.

In detail, the device 10 comprises a sense anchoring region 24c fixed to the frame body 12 and extending on the upper surface 12a of the frame body 12 along the Z-axis. The sense structure 28 is elastically coupled to the sense anchoring region 24c.

In the embodiment exemplarily described in FIG. 1, the third oscillation direction 22c is shown parallel to the X-axis, indicating that the sense structure 28 can move along the X-axis, away from or toward the sense anchoring region 24c. Nevertheless, other embodiments may similarly be considered, for example in which the sense structure 28 moves along the Y-axis or the Z-axis, or along any combination of these axes. In the following description, for simplicity, reference is made only to the case in which the third oscillation direction 22c is parallel to the X-axis.

As shown in FIG. 1, the sense structure 28 extends above the frame body 12 along the Z-axis at a distance therefrom. In other words, the upper surface 12a of the frame body 12 faces the sense structure 28 along the Z-axis.

Furthermore, in FIG. 1 the sense structure 28 faces, at least in part, the second side wall 18b of the seismic mass 18 along the X-axis and therefore along the first oscillation direction 22a. Nevertheless, other arrangements may similarly be considered, for example the sense structure 28 may face, even only in part, the first side wall 18a of the seismic mass 18 along the first oscillation direction 22a.

In particular, the device 10 further comprises a sense elastic group 36 interposed, here exemplarily along the X-axis, between the sense structure 28 and the sense anchoring region 24c. Nevertheless, other embodiments may similarly be considered, for example in which the sense elastic group 36 is interposed between the sense structure 28 and the upper surface 12a of the frame body 12 along the Z-axis. In the following description, for simplicity, reference is made to the case in which the sense elastic group 36 is interposed between the sense structure 28 and the sense anchoring region 24c.

The sense elastic group 36, of the elastic type, elastically couples the sense structure 28 to the frame body 12, allowing movement of the sense structure 28 along the third oscillation direction 22c during use.

In detail, the sense elastic group 36 comprises one or more sense elastic elements, such as springs, for example of the folded type, which may have a bellows or serpentine path and are elastically deformable along the third oscillation direction 22c.

In the example of FIG. 1, only a first sense elastic element 36’ is present, interposed between the sense structure 28 and the sense anchoring region 24c. Nevertheless, other numbers and arrangements of sense elastic elements may similarly be considered.

The device 10 further comprises a fixed sense element (or fixed sense stopper element) 38 and a fixed sense actuation element 40, fixed to the frame body 12 and defining a sense actuation group configured to control the position of the sense structure 28. In the case of multiple sense structures 28, a respective fixed sense element 38 and a respective fixed sense actuation element 40 are provided for each sense structure 28.

The fixed sense element 38 and the fixed sense actuation element 40 extend on the upper surface 12a of the frame body 12 at a distance from the sense structure 28 and face the sense structure 28 along the third oscillation direction 22c.

The fixed sense element 38 and the fixed sense actuation element 40 are shown arranged side by side along the Y-axis and facing the same side of the sense structure 28. Nevertheless, other arrangements may similarly be considered, as better described below.

Along the third oscillation direction 22c, the fixed sense element 38 is closer to the sense structure 28 than the fixed sense actuation element 40.

The fixed sense actuation element 40 is configured to control the position of the sense structure 28 with respect to the frame body 12, in particular capacitively. In use, the fixed sense actuation element 40 is electrically controllable so as to generate an electrostatic force (also referred to as the electrostatic sense force) between the fixed sense actuation element 40 and the sense structure 28, which moves the sense structure 28 toward the fixed sense element 38 along the third oscillation direction 22c.

The fixed sense element 38 is instead a stopper element configured to limit movement of the sense structure 28. Given the relative positions of the fixed sense element 38 and the fixed sense actuation element 40 with respect to the sense structure 28, when the electrostatic force between the fixed sense actuation element 40 and the sense structure 28 is greater than a threshold value, the sense structure 28 abuts against (i.e., is in contact with) the fixed sense element 38, thus preventing the sense structure 28 from impacting the fixed sense actuation element 40.

Accordingly, during use, the sense structure 28 is operable in a free state (or first state, oscillation state) or in a contact state (or second state, fixed state). In the free state, the electrostatic force between the fixed sense actuation element 40 and the sense structure 28 is lower than the threshold value and thus the sense structure 28 is at a distance from the fixed sense element 38 (free position of the sense structure 28) and is free to move along the third oscillation direction 22c. In the contact state, the electrostatic force between the fixed sense actuation element 40 and the sense structure 28 is equal to, or greater than, the threshold value and therefore the sense structure 28 is in contact with the fixed sense element 38 (contact position of the sense structure 28) and the electrostatic force prevents it from continuing to move along the third oscillation direction 22c, stacking it in its contact position.

Accordingly, the sense structure 28, the sense anchoring region 24c, the sense elastic group 36, the fixed sense element 38, and the fixed sense actuation element 40 together define a sense group 44, wherein the sense structure 28 is movable with respect to the frame body 12 and electrically controllable.

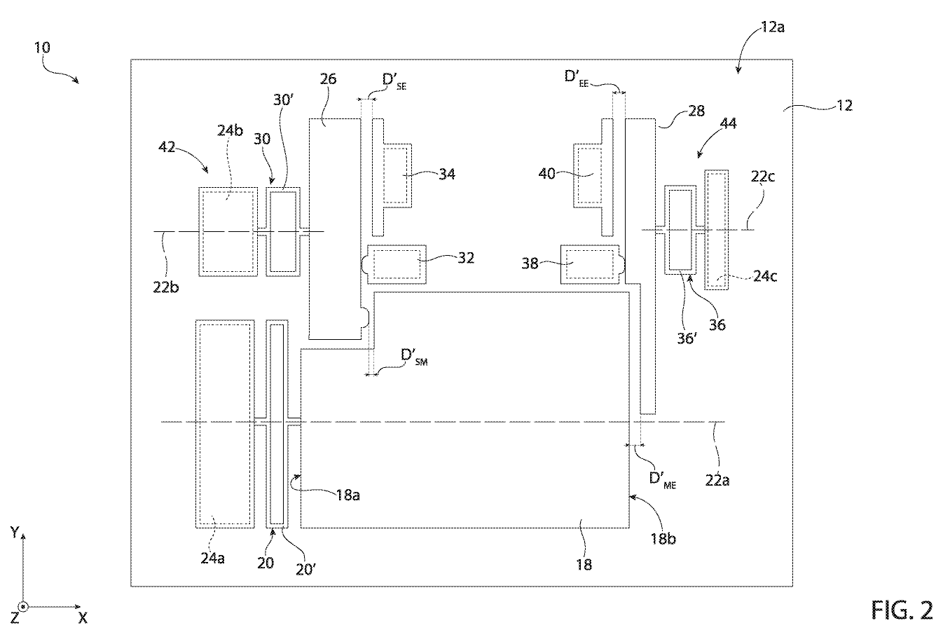

In detail, FIG. 1 shows the stopper structure 26 and the sense structure 28 in their respective free states, while FIG. 2 shows the stopper structure 26 and the sense structure 28 in their respective contact states. In both FIGS. 1 and 2, it is exemplarily assumed that the seismic mass 18 does not undergo acceleration along the first oscillation direction 22a, corresponding to a static state of the seismic mass 18. Furthermore, in FIG. 1 it is exemplarily assumed that the electrostatic forces acting on the stopper structure 26 and on the sense structure 28 are zero.

With reference to FIG. 2, in the contact state and along the X-axis, the stopper structure 26 and the seismic mass 18 are separated by a first distance therebetween (also referred to as the first stopper-mass distance) D_{’} _{SM}. The stopper structure 26 and the fixed stopper actuation element 34 are separated by a first distance therebetween (also referred to as the first stopper-electrode distance, in particular a minimum distance) D_{’SE}; the sense structure 28 and the seismic mass 18 are separated by a first distance therebetween (also referred to as the first mass-electrode distance) D_{ME}’. The sense structure 28 and the fixed sense actuation element 40 have a first distance therebetween (also referred to as the first electrode-electrode distance, in particular a minimum distance) D_{EE}’.

In detail, D_{’} _{SM} is smaller than D_{’} _{ME}, so that the seismic mass 18 cannot impact the sense structure 28 when the seismic mass 18 undergoes acceleration along the first oscillation direction 22a, corresponding to a dynamic state of the seismic mass 18.

With reference to FIG. 1, in the free state and along the X-axis, the stopper structure 26 and the seismic mass 18 are separated by a second distance therebetween (also referred to as the second stopper-mass distance) D_{”} _{SM}. The stopper structure 26 and the fixed stopper actuation element 34 are separated by a second distance therebetween (also referred to as the second stopper-electrode distance) D_{”} _{SE}. The stopper structure 26 and the fixed stopper element 32 have a distance therebetween (also referred to as the stopper-stopper distance) D_{SS}. The sense structure 28 and the seismic mass 18 are separated by a second distance therebetween (also referred to as the second mass-electrode distance) D_{ME}”. The sense structure 28 and the fixed sense actuation element 40 have a second distance therebetween (also referred to as the second electrode-electrode distance) D_{EE}”. The sense structure 28 and the fixed sense element 38 are separated by an electrode‑stopper distance DES.

In detail, D_{”} _{SM} is smaller than D_{”} _{ME}, so that the seismic mass 18 cannot impact the sense structure 28 when the seismic mass 18 undergoes acceleration along the first oscillation direction 22a. Furthermore, D_{SS} is smaller than D_{”} _{SE}, so that the stopper structure 26 cannot impact the fixed stopper actuation element 34 when the electrostatic force acts along the second oscillation direction 22b. Additionally, D_{ES} is smaller than D_{”} _{EE}, so that the sense structure 28 cannot impact the fixed sense actuation element 40 when the electrostatic force acts along the third oscillation direction 22c.

More specifically, D_{”} _{SE} equals D_{SS} plus D_{’} _{SE}, D_{”} _{EE} equals D_{ES} plus D_{’} _{EE}, D_{”} _{SM} equals D_{SS} plus D_{’} _{SM}, and D_{”} _{ME} equals D_{ES} plus D_{’} _{ME}.

As is evident, and although not shown in FIGS. 1 and 2, for improved operation the device 10 may have a symmetrical structure with respect to a first symmetry plane, not shown, parallel to an XZ plane defined by the X-axis and the Z-axis and passing through the first oscillation direction 22a, and with respect to a second symmetry plane, not shown, parallel to a YZ plane defined by the Y-axis and the Z-axis and orthogonal to the first oscillation direction 22a. This configuration may be achieved through the presence of multiple stopper groups 42 and multiple sense groups 44, not shown but arranged symmetrically with respect to the seismic mass 18, as better described below.

In use, the stopper structure 26 and the fixed stopper actuation element 34 are electrically biased so as to generate the electrostatic force previously described above, which is of the attractive type. In other words, the stopper structure 26 and the fixed stopper actuation element 34 define respective plates of a stopper capacitor, with a distance between the plates that is controllable through the applied electrical bias.

In particular, during use the stopper structure 26 is set at a rotor voltage Vrot (e.g., comprised between about 0 V and about 2 V and for example equal to about 1 V) and the fixed stopper actuation element 34 is set at a first actuation voltage Vact1 (e.g., comprised between about 3 V and about 5 V and for example equal to about 4 V). The potential difference between the stopper structure 26 and the fixed stopper actuation element 34 allows capacitive control of the position of the stopper structure 26 with respect to the fixed stopper actuation element 34.

For example, although not shown, the stopper structure 26 may be electrically connected to a rotor pad configured to be biased to the rotor voltage Vrot, while the fixed stopper actuation element 34 may be electrically connected, through a conductive track, to a first actuator pad configured to be biased to the first actuation voltage Vact1.

Furthermore, the mass anchoring region 24a, the stopper anchoring region 24b, the seismic mass 18, and the fixed stopper element 32 may also be biased to the rotor voltage Vrot, so as to avoid generating unwanted electrostatic forces with the stopper structure 26. In this case, for example, the mass anchoring region 24a, the stopper anchoring region 24b, the seismic mass 18 and the fixed stopper element 32 may also be electrically connected to the first actuator pad through respective conductive tracks.

Similarly, the sense structure 28 and the fixed sense actuation element 40 are electrically biased so as to generate the electrostatic force described above, which is of the attractive type. In other words, the sense structure 28 and the fixed sense actuation element 40 define respective plates of a sense capacitor, with a distance between the plates that is controllable through the applied electrical bias.

In particular, the sense structure 28 is set to a stator voltage Vstat (e.g., comprised for example between about 0 V and about 2 V, and for example equal to about 0.5 V), and the fixed sense actuation element 40 is set to a second actuation voltage V_{act2} (e.g., comprised, for example between about 3 V and about 5 V, and for example equal to about 4 V). The potential difference between the sense structure 28 and the fixed sense actuation element 40 allows capacitive control of the position of the sense structure 28 with respect to the fixed sense actuation element 40.

For example, although not shown, the sense structure 28 may be electrically connected to a stator pad configured to be biased to the stator voltage Vstat, while the fixed sense actuation element 40 may be electrically connected, through a conductive track, to a second actuator pad configured to be biased to the second actuation voltage Vact2.

Furthermore, the sense anchoring region 24c and the fixed sense element 38 may also be biased to the stator voltage Vstat, so as to avoid generating unwanted electrostatic forces with the sense structure 28. For example, the sense anchoring region 24c and the fixed sense element 38 may also be electrically connected to the second actuator pad, through respective conductive tracks.

Furthermore, the fixed stopper actuation element 34 and the fixed sense actuation element 40 may be biased to the same voltage (e.g., an actuation voltage V_{act}). In this case, the fixed stopper actuation element 34 and the fixed sense actuation element 40 may be electrically connected, through respective conductive tracks, to the same pad (also referred to as the actuator pad) configured to be biased to the actuation voltage Vact. This configuration reduces the number of pads of the device 10, saving space in the padout region and allowing a larger pitch or the inclusion of additional pads for other functions.

In use, the stopper structure 26 and the sense structure 28 are controlled to move along their respective oscillation directions 22b and 22c with respect to the frame body 12, in particular toward the fixed stopper element 32 and the fixed sense element 38, respectively.

In other words, during use the stopper structure 26 is controlled to move from a first position, corresponding to a rest state (i.e. when the stopper structure 26 is not electrically controlled), to a second position, corresponding to a control state (i.e. when the stopper structure 26 is electrically controlled). The first position corresponds to the position of the stopper structure 26 shown in FIG. 1, while the second position may correspond to the position of the stopper structure 26 shown in FIG. 2 or to any intermediate position between the rest state and the contact state.

In detail, the stopper structure 26 is farther from the fixed stopper element 32 in the first position than in the second position. In other words, the stopper structure 26 and the fixed stopper element 32 have a first relative distance therebetween in the first position of the stopper structure 26 and a second relative distance in the second position of the stopper structure 26, where the first relative distance corresponds to the distance D_{SS} and the second relative distance is lower than the distance D_{SS} (e.g., it is zero or comprised between a zero value and the distance D_{SS}, with the boundary values excluded). A similar consideration applies to the stopper structure 26 and the fixed stopper actuation element 34, as well as to the stopper structure 26 and the seismic mass 18.

Furthermore, during use the sense structure 28 is controlled to move from a first position, corresponding to a rest state (i.e., when the sense structure 28 is not electrically controlled), to a second position, corresponding to a control state (i.e., when the sense structure 28 is electrically controlled). The first position corresponds to the position of the sense structure 28 shown in FIG. 1, while the second position may correspond to the position of the sense structure 28 shown in FIG. 2 or to any intermediate position between the rest state and the contact state.

In detail, the sense structure 28 is farther from the fixed sense element 38 in the first position than in the second position. That is, the sense structure 28 and the fixed sense element 38 have a first relative distance in the first position of the sense structure 28 and a second relative distance in the second position of the sense structure 28, where the first relative distance corresponds to the distance D_{ES} and the second relative distance is lower than the distance D_{ES} (e.g., it is zero or comprised between a zero value and the distance D_{ES}, with the boundary values excluded). A similar consideration applies to the sense structure 28 and the fixed sense actuation element 40, as well as to the sense structure 28 and the seismic mass 18.

When the stopper structure 26 and the sense structure 28 are in their respective second positions, the device 10 is capable of operating, in a manner known per se and therefore not described in detail here, based on adjustable distances between the stopper structure 26 and the seismic mass 18 and between the sense structure 28 and the seismic mass 18. These adjustable distances are controllable by adjusting the electrical bias applied to the stopper structure 26 and the sense structure 28.

In particular, when the stopper structure 26 and the sense structure 28 are in their respective second positions, the seismic mass 18 can oscillate along the first oscillation direction 22a in response to accelerations to be measured. In this case, movement of the seismic mass 18 with respect to the frame body 12 is measured capacitively through the sense structure 28. Furthermore, if the acceleration exceeds an acceleration threshold value corresponding to a full‑scale value of the device 10, the seismic mass 18 abuts against the stopper structure 26 (i.e. the distance D_{’} _{SM} is zero), that limits its movements and therefore prevents the seismic mass 18 from being damaged.

In particular, it has been verified that, in this configuration, intrinsic dimensional loss and spread dimensional loss of cooperating elements substantially cancel each other in the calculation of certain distances described above. This allows distances between elements to be obtained that are substantially independent of these parameters and therefore more reliable than in known solutions. For example, intrinsic dimensional loss and spread dimensional loss of the distance D_{”} _{ME} compensate for intrinsic dimensional loss and spread dimensional loss of the distance D_{ES} in determining the distance D_{’} _{ME}. Consequently, the distance D_{’} _{ME} (and more generally the adjustable distance between the sense structure 28 and the seismic mass 18) is not influenced by intrinsic dimensional loss or spread dimensional loss.

This compensation effect is particularly effective when it concerns elements of the device 10 that have similar nature and structure (e.g., “bump” and “bump”, electrode and electrode) and that are close to each other: in this case, the steps for manufacturing these elements are often sufficiently similar to ensure that these elements have similar properties and manufacturing tolerances to each other, which leads to an intrinsic dimensional loss and a spread dimensional loss that are completely similar between these elements.

This conclusion also applies to other distances described (e.g., D_{’} _{SM} and more generally the adjustable distance between the stopper structure 26 and the seismic mass 18). However, it is particularly advantageous for the adjustable distance between the sense structure 28 and the seismic mass 18, since this distance determines the result of the capacitive measurement of the position of the seismic mass 18. In other words, having this distance (e.g., D_{ME}’) that does not depend on these critical parameters implies that the measurement of the acceleration is less affected by process spreads due to the manufacturing of the device 10, making the measurements carried out more reliable and robust.

Furthermore, during manufacturing of the device 10, the stopper structure 26 and the sense structure 28 are formed such that distances D_{”} _{SE}, D_{”} _{EE}, and D_{”} _{SM} are greater than the minimum dimension of the lithographic process used. Nevertheless, during use, when the stopper structure 26 and the sense structure 28 are in the control state, the adjustable distances (e.g., D_{’} _{SE}, D_{’} _{EE} and D_{’} _{SM}) may be smaller than the minimum dimension of the lithographic process used. Accordingly, the device 10 is not limited by lithographic minimum dimensions and can be scaled beyond current solutions. This is particularly advantageous for the adjustable distance between the stopper structure 26 and the seismic mass 18 (e.g., the distance D_{’SM}), because it allows to significantly reduce the dimension of the device 10 and increases its mechanical robustness.

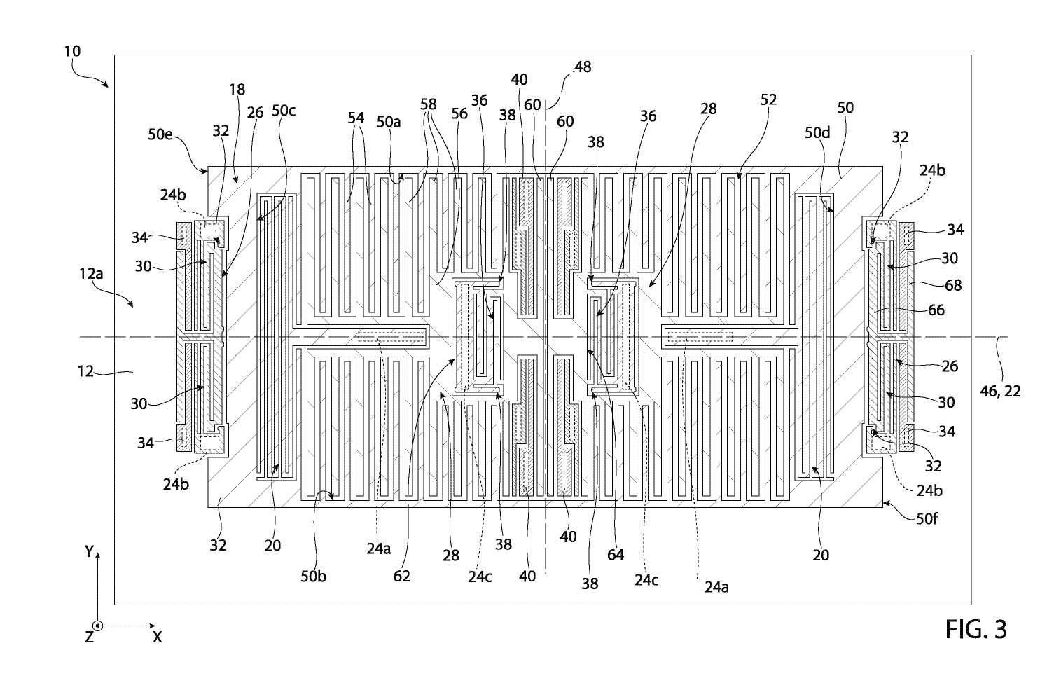

FIG. 3 shows the device 10 according to an exemplary embodiment.

The elements of the device 10 shown in FIG. 3 that are common to those of FIG. 1 are not described again in detail.

In particular, the device 10 of FIG. 3 is symmetrical with respect to a first median axis of symmetry 46 parallel to the X-axis and with respect to a second median axis of symmetry 48 parallel to the Y-axis.

In FIG. 3, the oscillation directions 22a, 22b, and 22c coincide. Accordingly, in the following description, reference is made to a single oscillation direction 22.

In detail, the oscillation direction 22 coincides with the first median axis of symmetry 46.

In FIG. 3, the seismic mass 18 comprises a main body 50 having internal side walls that delimit a through opening 52 extending through the main body 50 along the Z-axis. The main body 50 comprises a first internal side wall 50a and a second internal side wall 50b opposite each other along the Y-axis, orthogonal to the oscillation direction 22, and a third internal side wall 50c and a fourth internal side wall 50d opposite each other along the X-axis and along the oscillation direction 22.

The seismic mass 18 further comprises a plurality of ground electrodes 54 extending into the through opening 52, some from the first internal side wall 50a toward the second internal side wall 50b (without reaching the latter) and in part starting from the second internal side wall 50b and towards the first internal side wall 50a (without reaching the latter). Consequently, the ground electrodes 54 are carried by the main body 50 and are integral with the main body 50. In particular, the ground electrodes 54 have an elongated strip shape with their main extension parallel to the Y-axis. In other words, the ground electrodes 54 have a comb-like arrangement between each other.

Within the through opening 52, two sense groups 44 extend and are arranged symmetrically with respect to the second median axis of symmetry 48.

Each sense structure 28 comprises a respective main body 56 coupled to the sense elastic group 36 and a respective plurality of sense electrodes 58 carried by and integral with the main body 56. The sense electrodes 58 extend into the through opening 52 and have an elongated strip shape with their main extension parallel to the Y-axis. In other words, the sense electrodes 58 have a comb-like arrangement between each other.

The sense electrodes 58 and the ground electrodes 54 are interdigitated so as to allow capacitive sensing of the position of the seismic mass 18. For each pair of a sense electrode 58 and a ground electrode 54, their relative distance in the free state along the oscillation direction 22 defines the distance D_{”ME} previously described.

Furthermore, each sense structure 28 comprises one or more sense actuation electrodes 60 carried by the main body 56 and therefore integral therewith. The sense actuation electrodes 60 extend into the through opening 52 and have an elongated strip shape with their main extension parallel to the Y-axis.

The sense actuation electrodes 60 face a corresponding number of fixed sense actuation elements 40 and are separated from them, along the oscillation direction 22 and in the free state, by the distance D_{”} _{EE}. Accordingly, the sense actuation electrodes 60 and the fixed sense actuation elements 40 are capacitively coupled during use and control the position of the sense structure 28 with respect to the frame body 12.

For illustrative purposes, in FIG. 3 the main body 56 has a respective through opening 62 and a lateral internal wall 64 that faces the through opening 62 and that extends orthogonally to the oscillation direction 22.

The sense anchoring region 24c is located within the through opening 62 in top view, as is the sense elastic group 36, which elastically couples the sense anchoring region 24c to the lateral internal wall 64.

Furthermore, the fixed sense element 38 is defined by an elongated element having its main extension parallel to the oscillation direction 22. The fixed sense element 38 extends from the sense anchoring region 24c toward the lateral internal wall 64 and is positioned laterally to the sense elastic group 36 along the Y-axis. In detail, the end of the fixed sense element 38, that is opposite to the sense anchoring region 24c along the direction of the Y-axis, is at a distance D_{ES} from the lateral internal wall 64 in the free state and is in contact with the latter in the contact state.

Instead, the sense actuation electrodes 60 and the sense electrodes 58 are external to the through opening 62 and are arranged symmetrically with respect to the first median axis of symmetry 46.

Furthermore, in the example of FIG. 3, two pairs of mass anchoring regions 24a and mass elastic groups 20 are shown, positioned within the through opening 52 in top view and arranged symmetrically with respect to the second median axis of symmetry 48. Each mass elastic group 20 connects the respective mass anchoring region 24a to one of the third and fourth internal side walls 50c and 50d.

Furthermore, the seismic mass 18 has a first external side wall 50e and a second external side wall 50f facing towards the outside of the seismic mass 18 and opposite to each other along the oscillation direction 22.

In FIG. 3, the device 10 comprises two stopper groups 42, arranged symmetrically to each other with respect to the second median axis of symmetry 48 and each facing a respective one of the first external side wall 50e and the second external side wall 50f.

Each stopper structure 26 comprises a contact region 66 and one or more stopper electrodes 68 joined to and integral with the contact region 66.

The contact region 66 faces the respective external side wall 50e or 50f and is separated therefrom by the distance D_{”} _{SM} in the free state along the oscillation direction 22.

The contact region 66 is elastically coupled to the stopper anchoring region 24b through the corresponding stopper elastic group 30.

Furthermore, the stopper electrodes 68 face a corresponding number of fixed stopper actuation elements 34 and are separated therefrom by the distance D_{”} _{SE} in the free state along the oscillation direction 22. Accordingly, the stopper electrodes 68 and the fixed stopper actuation elements 34 are capacitively coupled during use and control the position of the stopper structure 26 with respect to the frame body 12.

In FIG. 3, each fixed stopper element 32 is defined by a protrusion fixed to the corresponding stopper anchoring region 24b. The protrusion extends toward the contact region 66 and is separated therefrom by the distance D_{SS} in the free state along the oscillation direction 22.

The device 10 shown in FIGS. 1 and 3 is manufactured using a manufacturing process comprising forming, on the frame body 12, the seismic mass 18 elastically coupled to the frame body 12 and configured to oscillate with respect to the frame body 12; forming, on the frame body 12, the mass elastic group 20 interposed between the seismic mass 18 and the frame body 12 and configured to elastically couple the seismic mass 18 to the frame body 12; and forming, on the frame body 12, the stopper structure 26, the stopper elastic group 30, and the stopper actuation group comprising elements 32 and 34, and/or forming, on the frame body 12, the sense structure 28, the sense elastic group 36, and the sense actuation group comprising elements 38 and 40.

From an examination of the characteristics of the invention made according to the present invention, the advantages that it affords are evident.

In particular, the present device 10 does not suffer from design constraints related to the minimum dimension of the lithographic process used during manufacturing and is therefore more scalable than known devices.

Furthermore, the spread of measurement sensitivity is significantly reduced, thereby increasing measurement reliability of the device 10.

Finally, it is clear that modifications and variations may be made to the invention described and illustrated herein without departing from the scope of the present invention as defined in the appended claims.

For example, the different embodiments described may be combined with each other to provide further solutions.

Furthermore, the device 10 may also be a biaxial or triaxial-type accelerometer, or a gyroscope or other similar MEMS device.

1. A microelectromechanical (MEMS) device, comprising:
a frame body;
a seismic mass elastically coupled to the frame body and configured to oscillate with respect to the frame body;
a stopper structure elastically coupled to the frame body and configured to move with respect to the frame body and to limit movement of the seismic mass with respect to the frame body; and
a stopper actuation group fixed to the frame body and configured to control position of the stopper structure with respect to the frame body in such a way as to vary an adjustable distance between the stopper structure and the seismic mass.

2. The device according to claim 1, wherein the stopper actuation group is electrically controllable to move the stopper structure from a first position to a second position, the adjustable distance between the stopper structure and the seismic mass being smaller in the second position of the stopper structure than in the first position of the stopper structure.

3. The device according to claim 1, wherein the stopper actuation group is configured to selectively control the stopper structure in a free state or in a contact state,
wherein, in the free state, the stopper structure is at a distance from the stopper actuation group and is movable with respect to the frame body, and
wherein, in the contact state, the stopper structure is in contact with the stopper actuation group and is fixed with respect to the frame body.

4. The device according to claim 3, wherein the stopper structure has a first stopper-mass distance from the seismic mass in the contact state and has a second stopper-mass distance from the seismic mass in the free state, the first stopper-mass distance being lower than the second stopper-mass distance,
wherein the first stopper-mass distance is zero when the seismic mass is subject to an acceleration equal to, or greater than, an acceleration threshold value.

5. The device according to claim 4, wherein the stopper actuation group comprises a fixed stopper element and a fixed stopper actuation element, fixed to the frame body,
wherein the fixed stopper actuation element is electrically controllable to move the stopper structure towards the fixed stopper element, and
wherein the fixed stopper element is configured to limit the movement of the stopper structure with respect to the frame body.

6. The device according to claim 5, wherein, in the contact state, the stopper structure has a first stopper-electrode distance from the fixed stopper actuation element and is in contact with the fixed stopper element, and
wherein, in the free state, the stopper structure has a second stopper-electrode distance from the fixed stopper actuation element and has a stopper-stopper distance from the fixed stopper element, the second stopper-electrode distance being greater than the first stopper-electrode distance.

7. The device according to claim 5, wherein the seismic mass is configured to oscillate with respect to the frame body along an oscillation direction,
wherein the seismic mass has a first external side wall and a second external side wall, opposite to each other along the oscillation direction,
wherein the device comprises a respective stopper structure and a respective stopper actuation group for each of the first and second external side walls,
wherein each stopper structure comprises at least one respective contact region and at least one respective stopper electrode joined to the contact region,
wherein, in each stopper structure, the contact region is elastically coupled to the frame body, faces the respective first or second external side wall along the oscillation direction, is configured to be in contact with the respective fixed stopper element in the contact state and be at a distance from the respective fixed stopper element in the free state, and is configured to be in contact with the respective first or second external side wall when the seismic mass is subject to an acceleration equal to, or greater than, the acceleration threshold value and be at a distance from the respective first or second external side wall when the seismic mass is subject to an acceleration lower than the acceleration threshold value, and
wherein, in each stopper structure, the stopper electrode faces the fixed stopper actuation element and is configured to cooperate capacitively with the fixed stopper actuation element.

8. The device according to claim 7, comprising the stopper structure, the stopper actuation group, the sense structure and the sense actuation group.

9. A microelectromechanical systems (MEMS) device, comprising:
a frame body;
a seismic mass elastically coupled to the frame body and configured to oscillate with respect to the frame body;
a sense structure elastically coupled to the frame body and configured to move with respect to the frame body and to sense position of the seismic mass; and
a sense actuation group fixed to the frame body and configured to control position of the sense structure with respect to the frame body in such a way as to vary an adjustable distance between the sense structure and the seismic mass.

10. The device according to claim 9, wherein the sense actuation group is electrically controllable to move the sense structure from a first position to a second position, the adjustable distance between the sense structure and the seismic mass being smaller in the second position of the sense structure than in the first position of the sense structure.

11. The device according to claim 9, wherein the sense actuation group is configured to selectively control the sense structure in a free state or in a contact state,
wherein, in the free state, the sense structure is at a distance from the sense actuation group and is movable with respect to the frame body, and
wherein, in the contact state, the sense structure is in contact with the sense actuation group and is fixed with respect to the frame body.

12. The device according to claim 11, wherein the sense structure has a first mass-electrode distance from the seismic mass in the contact state and has a second mass-electrode distance from the seismic mass in the free state, the first mass-electrode distance being smaller than the second mass-electrode distance,
wherein the first mass-electrode distance is zero when the seismic mass is subject to an acceleration equal to, or greater than, an acceleration threshold value.

13. The device according to claim 9, wherein the sense actuation group comprises a fixed sense element and a fixed sense actuation element, fixed to the frame body,
wherein the fixed sense actuation element is electrically controllable to move the sense structure towards the fixed sense element, and
wherein the fixed sense element is configured to limit movement of the sense structure with respect to the frame body.

14. The device according to claim 13,
wherein the sense actuation group is configured to selectively control the sense structure in a free state or in a contact state,
wherein, in the free state, the sense structure is at a distance from the sense actuation group and is movable with respect to the frame body,
wherein, in the contact state, the sense structure is in contact with the sense actuation group and is fixed with respect to the frame body,
wherein, in the contact state, the sense structure has a first electrode-electrode distance from the fixed sense actuation element and is in contact with the fixed sense element, and
wherein, in the free state, the sense structure has a second electrode-electrode distance from the fixed sense actuation element and has an electrode-stopper distance from the fixed sense element, the second electrode-electrode distance being greater than the first electrode-electrode distance.

15. The device according to claim 12,
wherein the sense actuation group comprises a fixed sense element and a fixed sense actuation element, fixed to the frame body,
wherein the fixed sense actuation element is electrically controllable to move the sense structure towards the fixed sense element,
wherein the fixed sense element is configured to limit movement of the sense structure with respect to the frame body,
wherein the seismic mass is configured to oscillate with respect to the frame body along an oscillation direction and extends on an upper surface of the frame body along a first axis,
wherein the seismic mass has a main body with first and second internal side walls that delimit a through opening that traverses the main body along the first axis, the internal side walls being opposite to each other along a second axis orthogonal to the first axis and to the oscillation direction,
wherein the seismic mass further comprises a plurality of ground electrodes that are carried by the main body of the seismic mass and extend in the through opening starting from the first internal side wall and towards the second internal side wall and/or starting from the second internal side wall and towards the first internal side wall,
wherein the sense structure extends in the through opening and comprises a respective main body, elastically coupled to the frame body, and a respective plurality of sense electrodes, carried by the main body of the sense structure and interdigitated with the ground electrodes in such a way as to be configured to cooperate capacitively with the ground electrodes for sensing the position of the seismic mass with respect to the frame body along the oscillation direction,
wherein the fixed sense actuation element and the fixed sense element extend in the through opening,
wherein the sense structure further comprises at least one sense actuation electrode that is carried by the main body, extends in the through opening and faces the fixed sense actuation element in such a way as to be configured to cooperate capacitively with the fixed sense actuation element for controlling the position of the sense structure with respect to the frame body, and
wherein the main body of the sense structure faces the fixed sense element and is configured to be in contact with the fixed sense element in the contact state and be at a distance from the fixed sense element in the free state, and
wherein the sense electrodes are at a distance from the ground electrodes.

16. The device according to claim 15, wherein the device is symmetrical with respect to a first median axis of symmetry coinciding with the oscillation direction and with respect to a second median axis of symmetry orthogonal to the oscillation direction and to the first axis.

17. A process for manufacturing a microelectromechanical systems (MEMS) device, comprising the steps of:
forming, on a frame body, a seismic mass elastically coupled to the frame body and configured to oscillate with respect to the frame body; and
forming, on the frame body, a stopper structure and a stopper actuation group, and/or forming, on the frame body, a sense structure and a sense actuation group,
wherein the stopper structure is elastically coupled to the frame body and is configured to move with respect to the frame body and to limit the movement of the seismic mass with respect to the frame body,
wherein the stopper actuation group is fixed to the frame body and is configured to control position of the stopper structure with respect to the frame body in such a way as to vary an adjustable distance between the stopper structure and the seismic mass,
wherein the sense structure is elastically coupled to the frame body and is configured to move with respect to the frame body and to sense position of the seismic mass,
wherein the sense actuation group is fixed to the frame body and is configured to control position of the sense structure with respect to the frame body in such a way as to vary a respective adjustable distance between the sense structure and the seismic mass.
